(19) United States
(12) Patent Application Publication
(10) Pub. No.: US 2023/0010328 A1
(43) Pub. Date: Jan. 12, 2023

(54) SHIELDED GATE TRENCH MOSFET WITH MULTIPLE STEPPED EPITAXIAL STRUCTURES

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 17/367,662

(22) Filed: Jul. 6, 2021

(51) Int. Cl. H01L 29/78

(52) U.S. Cl. CPC H01L 29/7813; H01L 29/7811

(57) ABSTRACT

The present invention introduces a new shielded gate trench MOSFETs wherein epitaxial layer having special multiple stepped epitaxial (MSE) layers with different doping concentrations decreasing in a direction from substrate to body regions, wherein each of the MSE layers has uniform doping concentration as grown. Specific on-resistance is significantly reduced with the special MSE structure. Moreover, in sore preferred embodiment, an MSO (multiple stepped oxide) structure is applied to the shielded gate structure to further reduce the specific on-resistance and enhance device ruggedness.

### FIELD OF THE INVENTION

This invention relates generally to semiconductor power devices, and more particularly, to a shielded gate trench (SGT) MOSFET (Metal Oxide Semiconductor Field Effect Transistor) having multiple stepped epitaxial (MSE) structure to improve the device performance,

### BACKGROUND OF THE INVENTION

FIGS. 1 shows a conventional SGT MOSFET with a uniform epitaxial layer which has much lower gate charge and specific on-resistance compared with traditional single gate trench MOSFETs as results of the existence of oxide charge balance region (as illustrated in FIG. 1) in drift region and thick oxide underneath gate electrode. However, as die size of the device becomes smaller due to cell pitches decrease, the conventional SGT MOSFETs confront avalanche capability degradation issue. Typically, two electric field and impact ionization peaks are located near channel region and trench bottom respectively, and the electric field near channel region is always higher than trench bottom in the uniform epitaxial layer, causing avalanche occurrence Bear the channel region. A parasitic bipolar transistor (n+/p/N) existing in the channel region is easily turned on resulting in device failure at lower avalanche energy ratings.

Therefore, there is a need to provide new device configurations such that above discussed problem and limitation can be resolved, and DC/AC performance and device ruggedness are further improved by reducing the electric field near channel region so that avalanche occurs at the trench bottom slot the channel region.

### SUMMARY OF THE INVENTION

The present invention provides new SGT MOSFETs wherein epitaxial layer having special multiple stepped epitaxial (MSE) layers with different doping concentrations decreasing stepwise in a direction from substrate to body regions, wherein each of the multiple stepped epitaxial layers has a uniform doping concentration as grown. With this novel MSE structure, specific on-resistance is significantly reduced as a result of thinner epitaxy thickness and higher doping concentrations in drift region at any desired breakdown voltage than conventional SGT MOSFETs. Since doping concentration near the channel region is the lowest, the electric field near channel region is lower than the trench bottom. The avalanche capability or device ruggedness is thus enhanced because the avalanche occurs at trench bottom not in channel region.

The specific on-resistance can be further reduced with combination of the MSE structure and multiple stepped oxide (MSO) structure by increasing higher doping concentration without degrading breakdown voltage. The MSO structure is a field plate oxide surrounded shielded gate electrode having multiple stepped oxide with varying thickness decreasing stepwise in a direction from substrate to body region, wherein each stepped oxide is uniform.

According to one aspect, the invention features an SGT MOSFET which is formed in an epitaxial layer of a first conductivity type extending over a substrate of the first conductivity type, the SGT MOSFET further comprising: a plurality of gate trenches surrounded by source regions of the first conductivity type are encompassed in body regions of a second conductivity type near a top surface of the epitaxial layer, each of the gate trenches is filled with a gate electrode and a shielded gate electrode; the shielded gate electrode is insulated from the epitaxial layer by a first insulating film, the gate electrode is disposed above the shielded gate electrode and insulated from the epitaxial layer by a gate oxide, the shielded gate electrode and the gate electrode are insulated from each other by an (Inter-Poly Oxide) IPO film, the gate oxide surrounding the, gate electrode has less thickness than the first insulating film; an oxide charge balance region is formed between adjacent of the gate trenches; the body regions, the shielded gate electrode and the, source regions are shorted together to a source metal through a plurality of trench contacts; and the epitaxial layer has the MSE layers with different doping concentrations decreasing stepwise in a direction from substrate to body region, wherein each of the MSE layers has a uniform doping concentration as grown.

According to another aspect, in some preferred embodiments, the epitaxial layer comprises at least two stepped epitaxial layers of different doping concentrations including a bottom epitaxial layer with a doping concentration D1 and a top epitaxial layer above the bottom epitaxial layer with a doping concentration D2, wherein D2<D1. in some other preferred embodiments, the epitaxial layer comprises at least three stepped epitaxial layers of different doping concentration including a bottom epitaxial layer with doping concentration D1, a middle epitaxial layer with doping concentration D2 and a top epitaxial layer with doping concentration D3, wherein D3<D2 <D1.

According to another aspect, in some preferred embodiments, the epitaxial layer has a bottom epitaxial layer above the substrate and beyond bottom of the gate trenches.

According to another aspect, in some preferred embodiments, the first insulating film is a single oxide film having inform thickness, In some other preferred embodiments, the first insulating film has multiple stepped oxide structure with thickness decreasing stepwise in a direction from the substrate to the body regions. In some other preferred embodiments, the first insulating film has two stepped oxide structure having a lower portion oxide along lower portion sidewalls and bottoms of the gate trenches with greater thickness than the upper portion oxide. In some other preferred embodiments, the first insulating film has three stepped oxide structure having a lower portion oxide along lower portion sidewalls and bottom of the gate trenches with greater thickness than a middle portion oxide, and the middle portion oxide having greater thickness than an upper portion oxide.

According to another aspect, in some preferred embodiments, each sidewall of the gate trenches is substantially vertical to top surface of the epitaxial layer and has an angle with top surface of the epitaxial layer ranging from 88 to 90 degree.

According to another aspect, in some preferred embodiments, the first conductivity type is N type and the, second conductivity type is P type. In some other preferred embodiments, the first conductivity type is P type and second conductivity is N type.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings;

FIG. 1 is a cross-sectional view of a conventional SGT MOSFET of prior art.

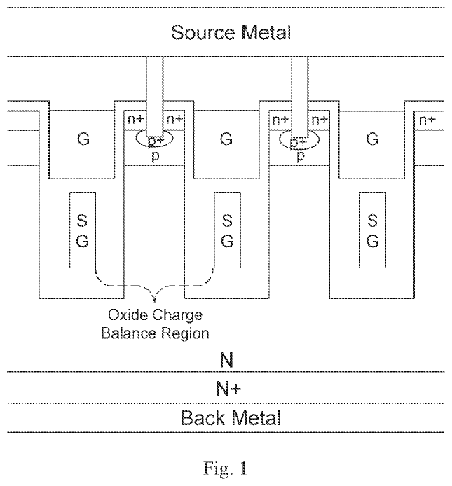

FIG. 2A is a cross-sectional view of a preferred embodiment with new and improved device structure having two stepped epitaxial layers wherein the doping concentration variations are depicted along the vertical direction according to the present invention.

FIG. 2B is a cross-sectional view of another preferred embodiment with new and unproved device stricture having two stepped epitaxial layers, and two stepped oxide structure as the first insulating film wherein the doping concentration variations are depicted along the vertical direction according to the present invention.

FIG. 2C is a crosssectional view of another preferred embodiment with new and improved device structure having two stepped epitaxial layers, and three stepped oxide structure as the first insulating film wherein the doping concentration variations are depicted along the vertical direction according to the present invention

FIG. 3A is a cross-sectional view of another preferred embodiment with new and improved device structure having three stepped epitaxial layers wherein the doping concentration variations are depicted along the vertical direction according to the present invention according to the present invent

FIG. 3B is a cross-sectional view of another preferred embodiment with new and improved device structure having three stepped epitaxial layers, and two stepped oxide structure as the first insulating film wherein the doping concentration variations are depicted along the vertical direction according to the present invention

FIG. 3C is a cross-sectional view of another preferred embodiment with new and improved device structure having three stepped epitaxial layers, and three stepped oxide structure as the first insulating film wherein the doping concentration variations are depicted along the vertical direction according to the present invention.

### DETAILED DESCRIPTION OF THE EMBODIMENTS

In the following Detailed Description reference is made to the accompanying drawings, which forms a part thereof, and in which is shown by way of illustration specific embodiments in which the invention may he practiced. In this regard, directional terminology, such as “top”, “bottom”, “front”, “back,”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims it is to be understood that the features of the various exemplary embodiments described herein may be combined with each other, unless specifically noted otherwise.

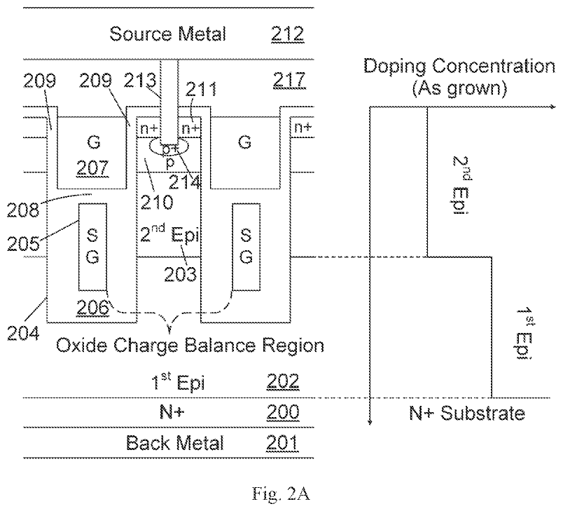

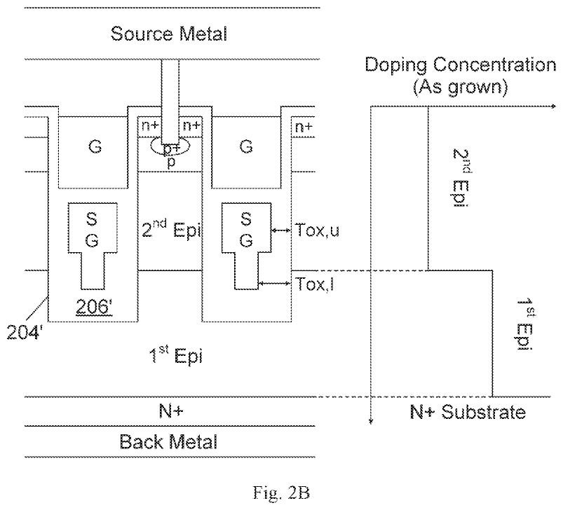

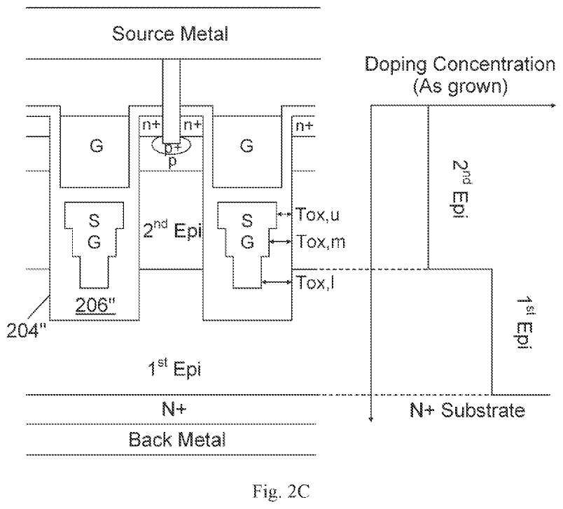

Please refer to FIG. 2A for a preferred embodiment of this invention with new and improved device structure having two stepped epitaxial layers wherein the doping concentration variations as grown are depicted along the vertical direction. The device comprises an N-channel SGT MOSFET formed in an N type epitaxial layer onto an N+substrate 200 coated with a back metal 201 of Ti/Ni/Ag on rear side as a drain metal. The N type epitaxial layer comprises a bottom 1^{st} epitaxial layer (1^{st} Epi, as illustrated) 202 with a doping concentration D1 and a top 2^{nd} epitaxial layer (2^{nd} Epi, as illustrated) 203 above the bottom epitaxial layer 202 with a doping concentration D2, wherein D2<D1, to increase the breakdown voltage and lower the specific on-resistance. Inside the N type epitaxial layer, a plurality of gate trenches 204 are formed extending from a top surface of the 2^{nd} epitaxial layer 203 and vertically downward into the 1² epitaxial layer 202, wherein trench bottoms of the gate trenches 204 are above a common interface between the N+substrate 200 and the 1^{st} epitaxial layer (1² Epi, as illustrated) 202. Inside each of the gate trenches 204, a shielded gate electrode (SG, as illustrated) 205 is disposed in the lower portion and a single gate electrode (G, as illustrated) 207 is disposed in the upper portion. The shielded gate electrode 205 is insulated from the adjacent epitaxial layer by a first insulating film 206 in drift regions below P body regions 210 and between adjacent gate trenches 204, and the gate electrodes 207 is insulated from the, adjacent epitaxial layer by a gate oxide 209, wherein the gate oxide 209 has a thinner thickness than the first insulating film 206 which has uniform thickness along trench sidewalls, meanwhile, the shielded gate electrode 205 and the gate electrode 207 is insulated from each other by an (Inter-Poly Oxide) IPO film 208. Between every two adjacent gate trenches 204, the P body regions 210 with n+ source regions 211 thereon are extending near top surface of the upper 2^{nd} epitaxial layer 203. The P body regions 210, the n+source regions 211 and the shielded gate electrodes 205 are further shorted together to a source metal 212 through a plurality of trenched contacts 213 filled with contact plugs and barriers implemented by penetrating through a contact insulating layer 217 and surrounded by p+heavily doped regions 214 around bottoms underneath the n+ source regions 211. According to the invention, an oxide charge balance region is therefore formed between adjacent of the gate trenches 204.

Please refer to FIG. 2B for another preferred embodiment of the present invention with new and improved device structure having two stepped epitaxial layers and Iwo stepped oxide structure wherein the duping concentration variations as grown are depicted along the vertical direction. The N-channel trenched semiconductor power device has a similar structure to FIG. 2A, except that, in FIG. 2B, the first insulating film 206′ in a single trench 204′ has two stepped oxide structure having a lower portion oxide along lower portion sidewalls and bottoms of the gate trenches 204 with a uniform first thickness Tox,l along trench sidewalk, and an upper portion oxide with a uniform second thickness Tox,u, where Tox,l is greater than Tox,u, to further reduce the on-resistance while maintaining the same breakdown voltage.

Please refer to FIG. 2C for another preferred embodiment of the present invention with new and improved device structure having two stepped epitaxial layers and three stepped oxide structure wherein the doping concentration variations as grown are depicted along the vertical direction. The N-channel trenched semiconductor power device has a similar structure to FIG. 2A, except that, in FIG. 2C, the first insulating film 206″ in a single trench 204″ has three stepped oxide structure having a lower portion oxide along lower portion sidewalls and bottom of the gate trenches 204″ with a uniform first thickness Tox,l, a middle portion oxide with a uniform second thickness Tox,m, and an upper portion oxide with a uniform third thickness Tox,u, where Tox,l is greater than Tox,m, and Tox,m is greater than Tox,u, to further reduce the on-resistance while maintaining the same breakdown voltage. The Tox,m can be the average of Tox,l and Tox,u.

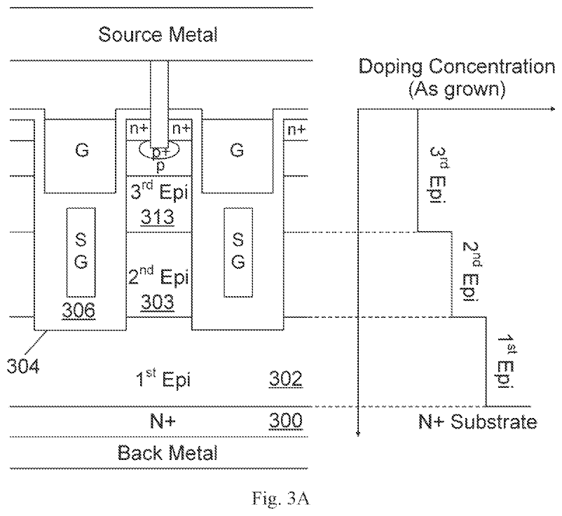

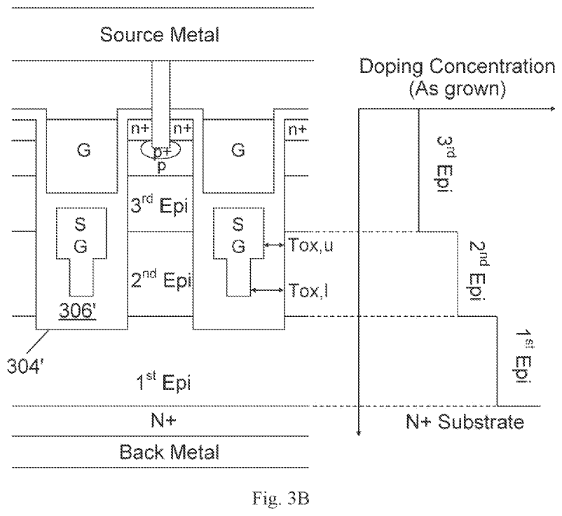

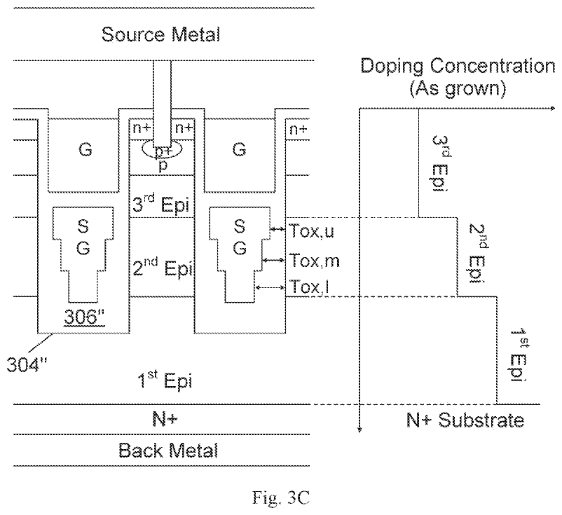

Please refer to FIG. 3A for another preferred embodiment of the present invention with new and improved device structure having three stepped epitaxial layers wherein the doping concentration variations as grown are depicted along the vertical direction. The N-channel trenched semiconductor power device has a similar structure to FIG. 2A, except that, in FIG. 3A, the N type epitaxial layer comprises three stepped epitaxial layers of different doping concentration including a bottom epitaxial layer (1^{st} Epi, as illustrated) 302 with doping concentration D1, a middle 2^{nd} epitaxial layer (2^{nd} Epi, as illustrated) 303 with doping concentration D2 and a top 3^{rd} epitaxial layer (3^{rd} Epi, as illustrated) 313 with doping concentration D3, wherein D3<D2<D1, to further reduce the specific on-resistance. The D2 can be the average of D1 and D3.

Please refer to FIG. 3B for another preferred embodiment of the present invention with new and improved device structure having three stepped epitaxial layers and two stepped oxide structure wherein the doping concentration variations as grown are depicted along the vertical direction. The N-channel trenched semiconductor power device has a similar structure to FIG. 3A, except that, in FIG. 3B, the first insulating film 306′ in a single trench 304′ has two stepped oxide structure having a lower portion oxide along lower portion sidewalls and bottoms of the gate trenches 304 with a uniform first thickness Tox,l along trench sidewalls, and an upper portion oxide with a uniform second thickness Tox,u, where Tox,l is greater than Tox,u, to further reduce the on-resistance while maintaining the same breakdown voltage.

Please refer to FIG. 3C for another preferred another present invention with new and improved device structure having three stepped epitaxial layers and three stepped oxide structure wherein the doping concentration variations are depicted along the vertical direction. The N-channel trenched semiconductor power device has a similar structure to FIG. 3A, except that, in FIG. 3C, the first insulating film 306″ in a single trench 304″ has three stepped oxide structure having a lower portion oxide along lower portion sidewalk and bottom of the gate trenches 304″ with a uniform first thickness Tox,l along trench sidewalk, a middle portion oxide with a uniform second thickness Tox,m, and art upper portion oxide with a uniform third thickness Tox,u, where Tox,l is greater than Tox,m, and Tox,m is greater than Tox,u, to further reduce the on-resistance while maintaining the same breakdown voltage. The Tox,m can be the average of Tox,l and Tox,u.

Although the present invention has been described in terms of the presently preferred embodiments, it is to be understood that such disclosure is not to he interpreted as limiting. The embodiments described above often show N-channel devices, the embodiments can also he applied to P-channels devices by reversing the polarities of the conductivity types. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A shielded gate trench MOFET formed in an epitaxial layer of a first conductivity type onto a substrate of said first conductivity type, further comprising:
a plurality of gate trenches surrounded by source regions of said first conductivity type We encompassed in body regions of a second conductivity type near a top surface of said epitaxial layer, each of said gate trenches is filled with a gate electrode and a shielded gate electrode; said shielded gate electrode is insulated from said epitaxial layer by a first insulating film, said gate electrode is insulated from said epitaxial layer by a gate oxide, said shielded gate electrode and said gate electrode are insulated from each other by an (Inter-Poly Oxide) IPO film, said gate oxide surrounds said gate electrode and has less thickness than said first insulating film;
an oxide charge balance region is formed between adjacent of said gate trenches;
said body regions, said shielded gate electrode and said source regions are shorted together to a source metal through a plurality of trench contacts;
said epitaxial layer has multiple stepped epitaxial (MSE) layers with different doping concentrations decreasing stepwise in a direction from substrate to said body regions, wherein each of said multiple stopped-epitaxial layers has uniform doping concentration as grown.

2. The SGT MOSFET of claim 1, wherein said gate electrode is disposed above said shielded gate electrode.

3. The SGT MOSFET of claim 1, wherein said epitaxial layer comprises at least two stepped epitaxial layers of different doping concentrations including a bottom epitaxial layer with a doping concentration DI and a top epitaxial layer above said bottom epitaxial layer with a doping concentration D2, wherein said D2<D1.

4. The SGT MOSFET of claim 1, wherein said epitaxial layer comprises at least three stepped epitaxial layers of different doping concentration including a bottom epitaxial layer with doping concentration D1, a middle epitaxial layer with doping concentration D2 and a top epitaxial layer with doping concentration D3, wherein said D3<D2<D1.

5. The SGT MOSFET of claim 4, wherein said D2 is the average of said D1 and said D3.

6. The SGT MOSFET of claim 1, wherein said multiple stepped epitaxial layers have a bottom epitaxial layer above said substrate and beyond bottom of said gate trenches.

7. The SGT MOSFET of claim 1, wherein said first insulating film is a single oxide film having uniform thickness along sidewalls of said gate trenches.

8. The SGT MOSFET of claim 1, wherein said first insulating film has multiple stepped oxide structure with thickness decreasing stepwise in a direction from said substrate to said body regions.

9. The SGT MOSFET of claim 8, wherein said first insulating film has two stepped oxide structure having a lower portion oxide with a thickness Tox,l along lower portion sidewalls and bottoms of said gate trenches, and an upper portion oxide with a thickness Tox,u, wherein said Tox,l>Tox,u.

10. The SGT MOSFET of claim 8, wherein said first insulating film has three stepped oxide structure having a lower portion oxide with a thickness Tox,l along lower portion sidewalls arid bottom of said gate trenches, a middle portion oxide with a thickness Tox,m, and an upper portion oxide with a thickness of Tox,u, wherein said Tox,l >Tox,m >Tox,u.

11. The SGT MOSFET of claim 10, wherein said Tox,m is the average of said Tox,l and said Tox,u.

12. The SGT MOSFET of claim 1, wherein each sidewall of said gate trenches is substantially vertical to top surface of said epitaxial layer and has an angle with top surface of said epitaxial layer ranging from 88 to 90 degree.

13. The SGT MOSFET of claim 1, wherein said first conductivity type is N type and said second conductivity type is P type.

14. The SGT MOSFET of claim 1, wherein said first conductivity type is P type and second conductivity is N type.
